(19) United States
(12) Patent Application Publication
(10) Pub. No.: US 2024/0056037 A1
(43) Pub. Date: Feb. 15, 2024

(54) DOHERTY AMPLIFIER

(71) Applicant: Mitsubishi Electric Corporation, Tokyo (JP)

(72) Inventors: Keigo NAKATANI, Tokyo (JP); Yutaro YAMAGUCHI, Tokyo (JP); Shuichi SAKATA, Tokyo (JP); Yuji KOMATSUZAKI, Tokyo (JP); Koji YAMANAKA, Tokyo (JP)

(73) Assignee: Mitsubishi Electric Corporation, Tokyo (JP)

(21) Appl. No.: 18/379,855

(22) Filed: Oct. 13, 2023

Related U.S. Application Data
(63) Continuation of application No. PCT/JP2021/018321, filed on May 14, 2021.

(51) Int. Cl. H03F 3/21; H03F 1/02; H03F 1/56

(52) U.S. Cl. CPC H03F 3/211; H03F 1/0288; H03F 1/565; H03F 2200/336; H03F 2200/222; H03F 2200/387; H03F 2200/171

(57) ABSTRACT

A Doherty amplifier includes: a carrier amplifier that amplifies a first signal; a peak amplifier that amplifies a second signal; and a synthesis circuit that synthesizes the first signal amplified by the carrier amplifier and the second signal amplified by the peak amplifier, and the synthesis circuit includes a bandpass filter circuit that includes parasitic capacitances at respective output sides of the carrier amplifier and the peak amplifier as capacitors.

### CROSS REFERENCE TO RELATED APPLICATIONS

This application is a Continuation of PCT International Application No. PCT/JP2021/018321 filed on May 14, 2021, which is hereby expressly incorporated by reference into the present application.

### TECHNICAL FIELD

The present disclosure relates to a Doherty amplifier.

### BACKGROUND ART

There is a Doherty amplifier that includes a carrier amplifier and a peak amplifier. The carrier amplifier is an amplifier that amplifies an amplification target signal irrespectively of electric power of the amplification target signal. The peak amplifier is an amplifier that amplifies an amplification target signal only when electric power of the amplification target signal is predetermined electric power or more.

An output side of the carrier amplifier includes a parasitic capacitance (hereinafter, referred to as a “first parasitic capacitance”), and an amplification factor of the carrier amplifier lowers more as the first parasitic capacitance is greater. An output side of the peak amplifier includes a parasitic capacitance (hereinafter, referred to as a “second parasitic capacitance”), and an amplification factor of the peak amplifier lowers more as the second parasitic capacitance is greater.

As for a technique that increases amplification efficiency of Doherty amplifiers, there is a Doherty amplifier disclosed in Patent Literature 1. The Doherty amplifier includes a first resonance circuit and a second resonance circuit that resonate when an amplification target signal has a certain frequency (hereinafter, referred to as a “resonance frequency”). Resonance of the first resonance circuit reduces an influence of a first parasitic capacitance on an amplification factor of a carrier amplifier. Resonance of the second resonance circuit reduces an influence of a second parasitic capacitance on an amplification factor of a peak amplifier.

### CITATION LIST

### Patent Literatures

Patent Literature 1: WO 2017/145258 A

### SUMMARY OF INVENTION

### Technical Problem

According to the Doherty amplifier disclosed in the patent literature, when the frequency of the amplification target signal is a frequency other than the resonance frequency, any one of the first resonance circuit and the second resonance circuit does not resonate. Hence, there is a problem that, when the frequency of the amplification target signal is the frequency other than the resonance frequency, an influence of the first parasitic capacitance and an influence of the second parasitic capacitance lower amplification efficiency of the Doherty amplifier.

The present disclosure has been made to solve the above problem, and an object of the present disclosure is to provide a Doherty amplifier that can prevent amplification efficiency from lowering due to an influence of a parasitic capacitance at an output side of each of a carrier amplifier and a peak amplifier in an operating frequency band of the Doherty amplifier.

### Solution to Problem

A Doherty amplifier according to the present disclosure includes: a carrier amplifier to amplify a first signal; a peak amplifier to amplify a second signal; and a synthesis circuit to synthesize the first signal amplified by the carrier amplifier and the second signal amplified by the peak amplifier, and the synthesis circuit includes a bandpass filter circuit that includes, as a capacitor, a parasitic capacitance at an output side of each of the carrier amplifier and the peak amplifier.

### Advantageous Effects of Invention

According to the present disclosure, it is possible to prevent amplification efficiency from lowering due to an influence of a parasitic capacitance at an output side of each of a carrier amplifier and a peak amplifier in an operating frequency band of the Doherty amplifier.

### BRIEF DESCRIPTION OF DRAWINGS

FIG. 1 is a configuration diagram illustrating a Doherty amplifier according to Embodiment 1.

FIG. 2 is a configuration diagram illustrating a phase adjustment circuit 5 of the Doherty amplifier according to Embodiment 1.

FIG. 3 is a configuration illustrating a synthesis circuit 8 of the Doherty amplifier according to Embodiment 1.

FIG. 4 is an explanatory view illustrating pass phase characteristics of each of the phase adjustment circuit 5 and the synthesis circuit 8.

FIG. 5 is an explanatory view illustrating a calculation result of return loss in the synthesis circuit 8 of the Doherty amplifier illustrated in FIG. 1.

FIG. 6 is an explanatory view illustrating a calculation result of a decrease amount of backoff efficiency of the Doherty amplifier illustrated in FIG. 1.

FIG. 7 is an explanatory view illustrating pass phase characteristics of each of a phase delay circuit and a synthesis circuit of a Doherty amplifier described in Patent Literature 1.

FIG. 8 is an explanatory view illustrating a calculation result of an efficiency decrease amount at a time of a saturation operation in the Doherty amplifier illustrated in FIG. 1.

FIG. 9 is a configuration diagram illustrating a Doherty amplifier according to Embodiment 2.

FIG. 10 is a configuration diagram illustrating a Doherty amplifier according to Embodiment 3.

### DESCRIPTION OF EMBODIMENTS

Hereinafter, embodiments for carrying out the present disclosure will be described with reference to the accompanying drawings to describe the present disclosure in more detail.

### Embodiment 1

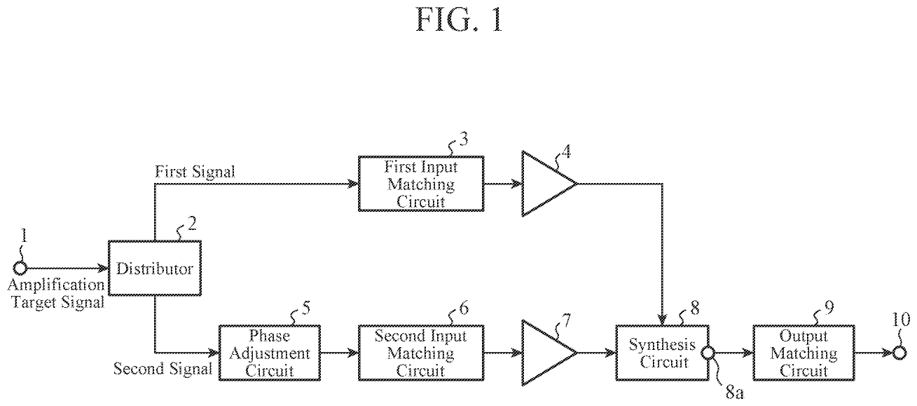

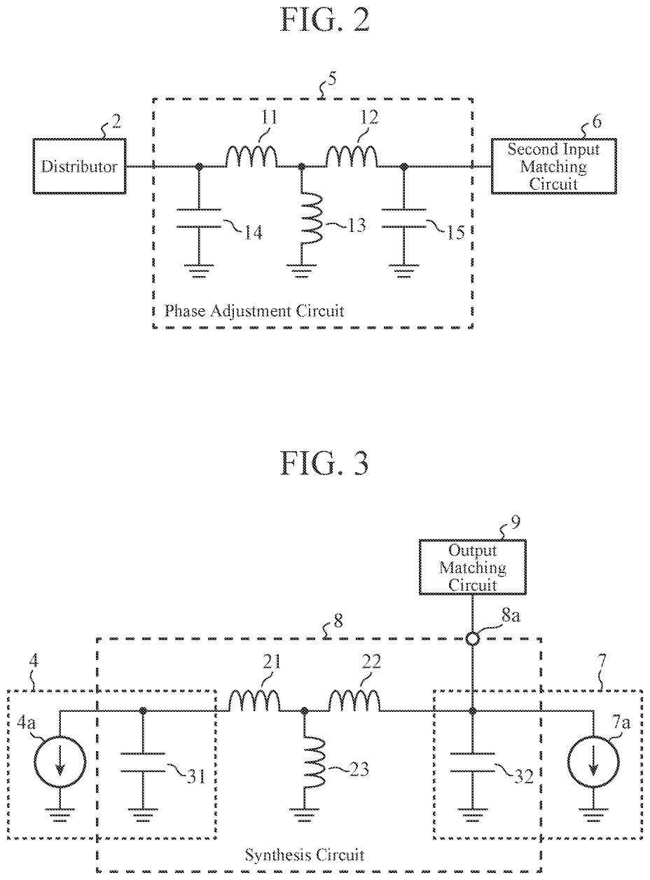

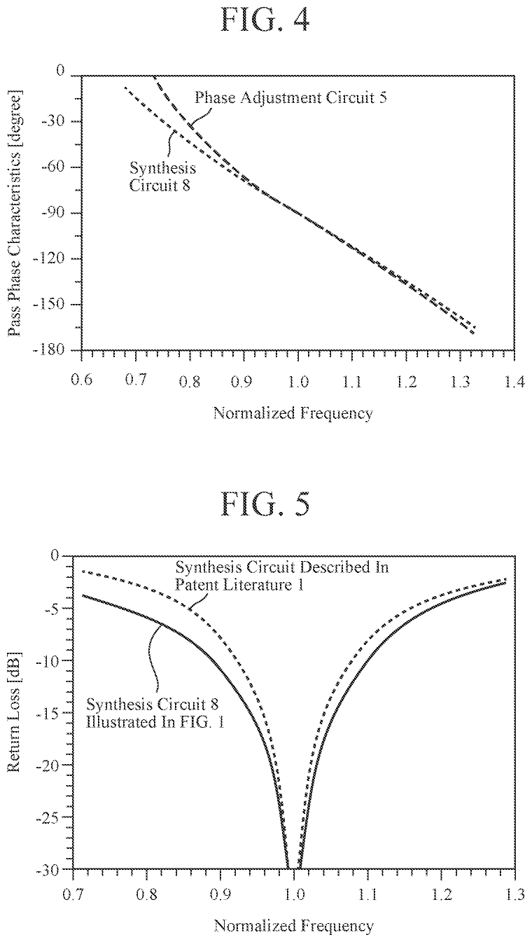

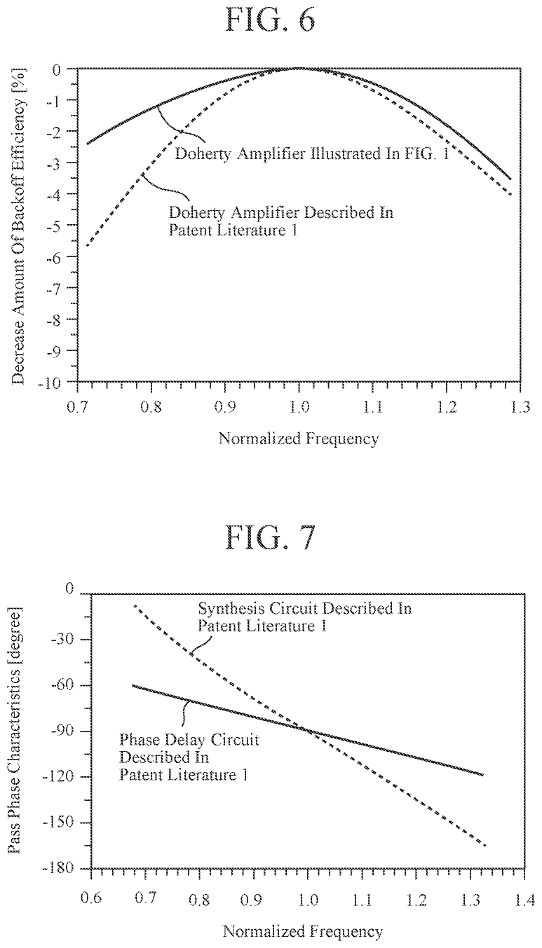

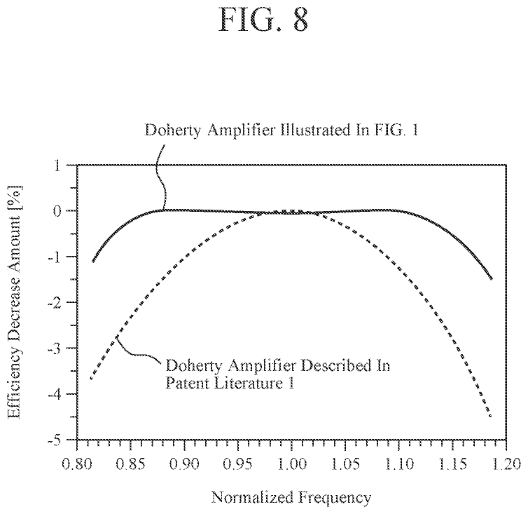

FIG. 1 is a configuration diagram illustrating a Doherty amplifier according to Embodiment 1.

The Doherty amplifier illustrated in FIG. 1 includes an input terminal 1, a distributor 2, a first input matching circuit 3, a carrier amplifier 4, a phase adjustment circuit 5, a second input matching circuit 6, a peak amplifier 7, a synthesis circuit 8, an output matching circuit 9, and an output terminal 10.

The Doherty amplifier illustrated in FIG. 1 is formed on, for example, a monolithic integrated circuit or a high frequency substrate.

The input terminal 1 is a terminal to which a high frequency signal is given as an amplification target signal from the outside of the Doherty amplifier.

The distributor 2 distributes, to two signals, electric power of the high frequency signal given to the input terminal 1.

The distributor 2 outputs one high frequency signal after power distribution as a first signal to the first input matching circuit 3, and outputs the other high frequency signal after power distribution to the phase adjustment circuit 5 as a second signal.

One end of the first input matching circuit 3 is connected with one output end of the distributor 2, and the other end of the first input matching circuit 3 is connected with an input end of the carrier amplifier 4.

The first input matching circuit 3 matches an impedance of the input end of the carrier amplifier 4 with an impedance of the input terminal 1.

The carrier amplifier 4 is implemented by an amplification element such as a Field Effect Transistor (FET), a Metal Oxide Semiconductor (MOS) transistor, or a bipolar transistor. Alternatively, the carrier amplifier 4 is implemented by an amplification circuit including an amplification element and an impedance conversion circuit.

The input end of the carrier amplifier 4 is connected with the other end of the first input matching circuit 3, and an output end of the carrier amplifier 4 is connected with one input end of the synthesis circuit 8.

The carrier amplifier 4 amplifies the first signal having passed through the first input matching circuit 3.

The carrier amplifier 4 outputs the amplified first signal to the synthesis circuit 8.

One end of the phase adjustment circuit 5 is connected with the other output end of the distributor 2, and the other end of the phase adjustment circuit 5 is connected with one end of the second input matching circuit 6.

The phase adjustment circuit 5 has the same pass phase characteristics as those of the synthesis circuit 8 in an operating frequency band of the Doherty amplifier.

The phase adjustment circuit 5 delays the phase of the second signal output from the distributor 2 by 90 degrees, and outputs the second signal after phase delay to the second input matching circuit 6.

In the Doherty amplifier illustrated in FIG. 1, the phase adjustment circuit 5 delays the phase of the second signal by 90 degrees in the operating frequency band of the Doherty amplifier. In this regard, a phase delay amount does not need to be strictly 90 degrees, and may be different from 90 degrees as long as there is no practical problem.

The one end of the second input matching circuit 6 is connected with the other end of the phase adjustment circuit 5, and the other end of the second input matching circuit 6 is connected with an input end of the peak amplifier 7.

The second input matching circuit 6 matches an impedance of the input end of the peak amplifier 7 with the impedance of the input terminal 1.

In the Doherty amplifier illustrated in FIG. 1, the second input matching circuit 6 is connected between the phase adjustment circuit 5 and the peak amplifier 7. However, this is merely an example, and the second input matching circuit 6 may be connected between the other output end of the distributor 2 and the phase adjustment circuit 5.

The peak amplifier 7 is implemented by an amplification element such as an FET, a MOS transistor, or a bipolar transistor. Alternatively, the peak amplifier 7 is implemented by an amplification circuit including an amplification element and an impedance conversion circuit.

The input end of the peak amplifier 7 is connected with the other end of the second input matching circuit 6, and an output end of the peak amplifier 7 is connected with the other input end of the synthesis circuit 8.

The peak amplifier 7 amplifies the second signal only when the electric power of the second signal having passed through the second input matching circuit 6 is predetermined electric power or more.

The peak amplifier 7 outputs the amplified second signal to the synthesis circuit 8.

The one input end of the synthesis circuit 8 is connected with the output end of the carrier amplifier 4, and the other input end of the synthesis circuit 8 is connected with the output end of the peak amplifier 7. Furthermore, a synthesis point 8a of the synthesis circuit 8 is connected with one end of the output matching circuit 9.

The synthesis circuit 8 delays the phase of the first signal amplified by the carrier amplifier 4 by 90 degrees.

The synthesis circuit 8 synthesizes the first signal after phase delay, and the second signal amplified by the peak amplifier 7.

The synthesis circuit 8 outputs a signal after the synthesis from the synthesis point 8a to the output matching circuit 9.

In the Doherty amplifier illustrated in FIG. 1, the synthesis circuit 8 delays the phase of the first signal by 90 degrees. In this regard, a phase delay amount does not need to be strictly 90 degrees, and may be different from 90 degrees as long as there is no practical problem.

The one end of the output matching circuit 9 is connected with the synthesis point 8a of the synthesis circuit 8, and the other end of the output matching circuit 9 is connected with the output terminal 10.

The output matching circuit 9 matches an impedance of the signal after the synthesis by the synthesis circuit 8 with an impedance of an unillustrated load.

The output terminal 10 is connected with the unillustrated load.

The output terminal 10 is a terminal for outputting, to the unillustrated load, the signal after the synthesis having passed through the output matching circuit 9.

FIG. 2 is a configuration diagram illustrating the phase adjustment circuit 5 of the Doherty amplifier according to Embodiment 1.

The phase adjustment circuit 5 illustrated in FIG. 2 includes a bandpass filter circuit.

The bandpass filter circuit includes inductors 11, 12, and 13 and capacitors 14 and 15.

One end of the inductor 11 is connected with each of the other output end of the distributor 2 and one end of the capacitor 14. The other end of the inductor 11 is connected with each of one end of the inductor 12 and one end of the inductor 13.

The one end of the inductor 12 is connected with each of the other end of the inductor 11 and the one end of the inductor 13. The other end of the inductor 12 is connected with each of one end of the capacitor 15 and the one end of the second input matching circuit 6.

The one end of the inductor 13 is connected with each of the other end of the inductor 11 and the one end of the inductor 12. The other end of the inductor 13 is connected with a ground.

The one end of the capacitor 14 is connected with each of the other output end of the distributor 2 and the one end of the inductor 11. The other end of the capacitor 14 is connected with a ground.

The one end of the capacitor 15 is connected with each of the other end of the inductor 12 and the one end of the second input matching circuit 6. The other end of the capacitor 15 is connected with a ground.

The bandpass filter circuit included in the phase adjustment circuit 5 illustrated in FIG. 2 includes the inductors 11, 12, and 13 and the capacitors 14 and 15. The bandpass filter circuit is only required to have the same pass phase characteristics as those of the synthesis circuit 8 in an operating frequency band of the Doherty amplifier, and to be a circuit that delays the phase of the second signal by 90 degrees. Hence, the configuration of the bandpass filter circuit is not limited to the configuration illustrated in FIG. 2, and may be a configuration including, for example, the inductors 11 and 12 and the capacitors 14 and 15.

The phase adjustment circuit 5 illustrated in FIG. 2 is formed by the inductors 11, 12, and 13 and the capacitors 14 and 15 that are lumped constant elements. However, this is merely an example, and the phase adjustment circuit 5 may be formed by distributed constant elements.

FIG. 3 is a configuration diagram illustrating the synthesis circuit 8 of the Doherty amplifier according to Embodiment 1.

The synthesis circuit 8 illustrated in FIG. 3 includes a bandpass filter circuit that includes parasitic capacitances at respective output sides of the carrier amplifier 4 and the peak amplifier 7 as capacitors 31 and 32.

The bandpass filter circuit includes inductors 21, 22, and 23 in addition to the capacitors 31 and 32.

A current source 4a is a current source of the carrier amplifier 4.

A current source 7a is a current source of the peak amplifier 7.

The capacitor 31 is the parasitic capacitance at the output side of the carrier amplifier 4, added to the current source 4a.

The capacitor 32 is the parasitic capacitance at the output side of the peak amplifier 7, added to the current source 7a.

The bandpass filter circuit included in the synthesis circuit 8 illustrated in FIG. 3 includes the inductors 21, 22, and 23 and the capacitors 31 and 32. The bandpass filter circuit is only required to have the same pass phase characteristics as those of the phase adjustment circuit 5 in the operating frequency band of the Doherty amplifier, and to be a circuit that delays the phase of the first signal by 90 degrees. Hence, the configuration of the bandpass filter circuit is not limited to the configuration illustrated in FIG. 3, and may be a configuration including, for example, the inductors 21 and 22 and the capacitors 31 and 32.

Next, the operation of the Doherty amplifier illustrated in FIG. 1 will be described.

A high frequency signal is given as an amplification target signal from the outside of the Doherty amplifier to the input terminal 1.

The distributor 2 distributes, to two signals, electric power of the high frequency signal given to the input terminal 1.

The distributor 2 outputs one high frequency signal after power distribution as the first signal to the first input matching circuit 3, and outputs the other high frequency signal after power distribution as the second signal to the phase adjustment circuit 5.

Distribution of the electric power to the two signals by the distributor 2 may be equal distribution, or may be unequal distribution.

The first signal output from the distributor 2 is given to the input end of the carrier amplifier 4 via the first input matching circuit 3.

The phase of the second signal output from the distributor 2 is delayed by 90 degrees by the phase adjustment circuit 5 in the operating frequency band of the Doherty amplifier.

The second signal whose phase is delayed by the phase adjustment circuit 5 is given to the input end of the peak amplifier 7 via the second input matching circuit 6.

The carrier amplifier 4 amplifies the first signal having passed through the first input matching circuit 3, and outputs the amplified first signal to the synthesis circuit 8.

The peak amplifier 7 does not perform an operation of amplifying the second signal when the electric power of the second signal having passed through the second input matching circuit 6 is less than the predetermined electric power. At this time, an impedance at a connection point between the peak amplifier 7 and the synthesis circuit 8 becomes infinite, and the connection point equivalently becomes an open end.

The peak amplifier 7 amplifies the second signal when the electric power of the second signal is the predetermined electric power or more, and outputs the amplified second signal to the synthesis circuit 8.

An operation of the peak amplifier 7 in a case where the electric power of the second signal to be given to the input end of the peak amplifier 7 is low, and therefore the electric power of the second signal amplified by the peak amplifier 7 is less than the electric power of the first signal amplified by the carrier amplifier 4, is referred to as a backoff operation. An operation of the peak amplifier 7 in a case where the electric power of the second signal to be given to the input end of the peak amplifier 7 is high, and therefore the electric power of the second signal amplified by the peak amplifier 7 is the same as the electric power of the first signal amplified by the carrier amplifier 4 is referred to as a saturation operation.

The synthesis circuit 8 delays the phase of the first signal amplified by the carrier amplifier 4 by 90 degrees in the operating frequency band of the Doherty amplifier.

The synthesis circuit 8 synthesizes the first signal after phase delay and the second signal amplified by the peak amplifier 7.

The signal after the synthesis by the synthesis circuit 8 is output from the synthesis point 8a to the output matching circuit 9.

In this regard, as illustrated in FIG. 3, the synthesis circuit 8 includes the bandpass filter circuit including the inductors 21, 22, and 23 and the capacitors 31 and 32.

The bandpass filter circuit is a circuit that delays the phase of the first signal by 90 degrees in the operating frequency band of the Doherty amplifier, and is not a resonance circuit that resonates at one certain frequency. The operating frequency band of the Doherty amplifier is a frequency band that includes a plurality of frequencies.

As illustrated in FIG. 2, the phase adjustment circuit 5 includes the bandpass filter circuit including the inductors 11, 12, and 13 and the capacitors 14 and 15.

The bandpass filter circuit is a circuit that delays the phase of the second signal by 90 degrees in the operating frequency band of the Doherty amplifier, and is not a resonance circuit that resonates at one certain frequency included in the operating frequency band of the Doherty amplifier.

The pass phase characteristics of the bandpass filter circuit included in the synthesis circuit 8, and the pass phase characteristics of the bandpass filter circuit included in the phase adjustment circuit 5 are substantially the same pass phase characteristics in the operating frequency band of the Doherty amplifier as illustrated in FIG. 4.

FIG. 4 is an explanatory view illustrating the pass phase characteristics of each of the phase adjustment circuit 5 and the synthesis circuit 8.

In FIG. 4, the horizontal axis indicates a normalized frequency, and the vertical axis indicates a pass phase [degree].

The broken line indicates the pass phase characteristics of the phase adjustment circuit 5, and the dotted line indicates the pass phase characteristics of the synthesis circuit 8. The operating frequency band of the Doherty amplifier is, for example, a normalized frequency of 0.9 to 1.1.

Consequently, the phase of the first signal whose phase is delayed by the synthesis circuit 8 and the phase of the second signal amplified by the peak amplifier 7 are substantially the same phase, so that an influence of the parasitic capacitance at the output side of each of the carrier amplifier 4 and the peak amplifier 7 is reduced.

The output matching circuit 9 matches the impedance of the signal after the synthesis by the synthesis circuit 8 with the impedance of the unillustrated load.

When, for example, an output impedance of each of the carrier amplifier 4 and the peak amplifier 7 is 50Ω, the impedance at the synthesis point 8a is 25Ω. When the impedance of the load is 50Ω, the output matching circuit 9 converts the impedance at the synthesis point 8a in such a way that the impedance at the synthesis point 8a is 50Ω.

The signal after the synthesis by the synthesis circuit 8 is given to the unillustrated load via the output matching circuit 9 and the output terminal 10.

FIG. 5 is an explanatory view illustrating a calculation result of return loss in the synthesis circuit 8 of the Doherty amplifier illustrated in FIG. 1.

In FIG. 5, the horizontal axis indicates a normalized frequency, and the vertical axis indicates return loss [dB].

The solid line indicates return loss of the synthesis circuit 8 of the Doherty amplifier illustrated in FIG. 1, and the broken line indicates return loss of a synthesis circuit described in Patent Literature 1.

According to the synthesis circuit described in Patent Literature 1, an operating frequency in a case where a normalized frequency is 1.0 is a resonance frequency of each of first and second resonance circuits.

According to a Doherty amplifier described in Patent Literature 1, when the operating frequency is the resonance frequency, an influence of a parasitic capacitance at an output side of each of a carrier amplifier and a peak amplifier is reduced. However, the first and second resonance circuits do not resonate when the operating frequency is a frequency other than the resonance frequency, and therefore the return loss of the synthesis circuit is great. That is, frequency characteristics of the return loss of the synthesis circuit described in Patent Literature 1 have a narrow band.

The synthesis circuit 8 of the Doherty amplifier illustrated in FIG. 1 includes the bandpass filter circuit that delays the phase of the first signal by 90 degrees in the operating frequency band of the Doherty amplifier, instead of the resonance circuit that resonates at one certain frequency. Accordingly, frequency characteristics of the return loss of the synthesis circuit 8 have a wider band than that of the frequency characteristics of the return loss of the synthesis circuit described in Patent Literature 1.

FIG. 6 is an explanatory view illustrating a calculation result of a decrease amount of the backoff efficiency of the Doherty amplifier illustrated in FIG. 1.

In FIG. 6, the horizontal axis indicates a normalized frequency, and the vertical axis indicates the decrease amount [%] of the backoff efficiency.

The solid line indicates the decrease amount of the backoff efficiency of the Doherty amplifier illustrated in FIG. 1, and the broken line indicates a decrease amount of backoff efficiency of the Doherty amplifier described in Patent Literature 1.

According to the Doherty amplifier described in Patent Literature 1, when the operating frequency is the resonance frequency, the influence of the parasitic capacitance at the output side of each of the carrier amplifier and the peak amplifier is reduced. However, the first and second resonance circuits do not resonate when the operating frequency is a frequency other than the resonance frequency, and therefore the decrease amount of the backoff efficiency of the Doherty amplifier is great. That is, frequency characteristics of the backoff efficiency of the Doherty amplifier described in Patent Literature 1 have a narrow band.

Each of the phase adjustment circuit 5 and the synthesis circuit 8 included in the Doherty amplifier illustrated in FIG. 1 is not the resonance circuit that resonates at one certain frequency, and includes the bandpass filter circuit that delays the phase by 90 degrees in the operating frequency band of the Doherty amplifier. Hence, the frequency characteristics of the backoff efficiency of the Doherty amplifier illustrated in FIG. 1 have a wider band than that of the frequency characteristics of the backoff efficiency of the Doherty amplifier described in Patent Literature 1.

FIG. 7 is an explanatory view illustrating pass phase characteristics of each of the phase delay circuit and the synthesis circuit of the Doherty amplifier described in Patent Literature 1.

In FIG. 7, the horizontal axis indicates a normalized frequency, and the vertical axis indicates a pass phase [degree].

The solid line indicates the pass phase characteristics of the phase delay circuit, and the dotted line indicates the pass phase characteristics of the synthesis circuit.

When the operating frequency is the resonance frequency, the pass phase of the phase delay circuit and the pass phase of the synthesis circuit match. However, when the operating frequency is a frequency other than the resonance frequency, the pass phase of the phase delay circuit and the pass phase of the synthesis circuit do not match. Hence, synthesis loss of the first signal and the second signal in the Doherty amplifier described in Patent Literature 1 becomes great at a time of a saturation operation, and the efficiency lowers.

As illustrated in FIG. 4, the pass phase characteristics of the phase adjustment circuit 5 and the pass phase characteristics of the synthesis circuit 8 are substantially the same pass phase characteristics in the operating frequency band, so that the Doherty amplifier illustrated in FIG. 1 has less synthesis loss of the first signal and the second signal at a time of the saturation operation than that of the Doherty amplifier described in Patent Literature 1.

FIG. 8 is an explanatory view illustrating a calculation result of an efficiency decrease amount at the time of the saturation operation in the Doherty amplifier illustrated in FIG. 1.

In FIG. 8, the horizontal axis indicates a normalized frequency, and the vertical axis indicates the efficiency decrease amount at the time of the saturation operation.

The solid line indicates the efficiency decrease amount at the time of the saturation operation in the Doherty amplifier illustrated in FIG. 1, and the broken line indicates an efficiency decrease amount at a time of a saturation operation in the Doherty amplifier described in Patent Literature 1.

According to the Doherty amplifier described in Patent Literature 1, when the operating frequency is the resonance frequency, the influence of the parasitic capacitance at the output side of each of the carrier amplifier and the peak amplifier is reduced. However, when the operating frequency is a frequency other than the resonance frequency, the first and second resonance circuits do not resonate, and therefore the efficiency decrease amount at the time of the saturation operation is great. That is, the frequency characteristics of efficiency at the time of the saturation operation in the Doherty amplifier described in Patent Literature 1 have a narrow band.

Each of the phase adjustment circuit 5 and the synthesis circuit 8 included in the Doherty amplifier illustrated in FIG. 1 is not the resonance circuit that resonates at one certain frequency, and includes the bandpass filter circuit that delays the phase of the corresponding signal by 90 degrees in the operating frequency band of the Doherty amplifier. Hence, the frequency characteristics of efficiency at the time of the saturation operation in the Doherty amplifier illustrated in FIG. 1 have a wider band than that of the frequency characteristics of the efficiency at the time of the saturation operation in the Doherty amplifier described in Patent Literature 1.

According to above Embodiment 1, the Doherty amplifier is configured to include: the carrier amplifier 4 that amplifies the first signal; the peak amplifier 7 that amplifies the second signal; and the synthesis circuit 8 that synthesizes the first signal amplified by the carrier amplifier 4 and the second signal amplified by the peak amplifier 7, and in such a way that the synthesis circuit 8 includes the bandpass filter circuit that includes the parasitic capacitances at the respective output sides of the carrier amplifier 4 and the peak amplifier 7 as the capacitors 31 and 32. Consequently, the Doherty amplifier can prevent amplification efficiency from lowering due to the influence of the parasitic capacitance at the output side of each of the carrier amplifier 4 and the peak amplifier 7 in the operating frequency band of the Doherty amplifier.

### Embodiment 2

The Doherty amplifier illustrated in FIG. 1 includes the first input matching circuit 3 and the second input matching circuit 6.

A Doherty amplifier that does not include the first input matching circuit 3 and the second input matching circuit 6 will be described in Embodiment 2.

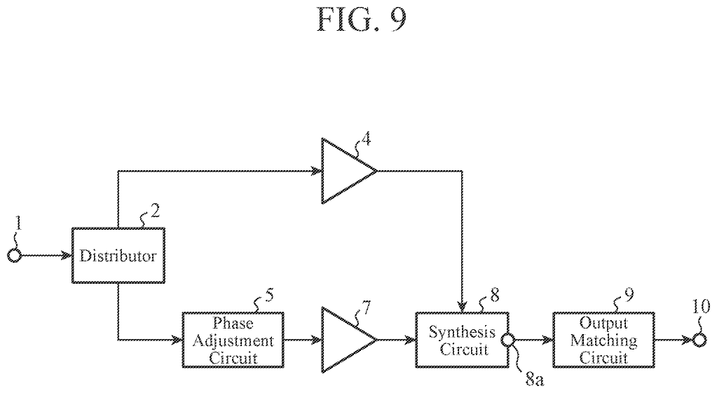

FIG. 9 is a configuration diagram illustrating the Doherty amplifier according to Embodiment 2.

The Doherty amplifier illustrated in FIG. 9 is the same as the Doherty amplifier illustrated in FIG. 1 except that the Doherty amplifier illustrated in FIG. 9 does not include the first input matching circuit 3 and the second input matching circuit 6.

In a case where an impedance of an input end of a carrier amplifier 4 is the same as an impedance of an input terminal 1, it is possible to omit the first input matching circuit 3.

In a case where an impedance of an input end of a peak amplifier 7 is the same as the impedance of the input terminal 1, it is possible to omit the second input matching circuit 6.

The Doherty amplifier illustrated in FIG. 9 can be miniaturized compared to the Doherty amplifier illustrated in FIG. 1.

### Embodiment 3

A Doherty amplifier to which amplification elements 51 and 52 are added will be described in Embodiment 3.

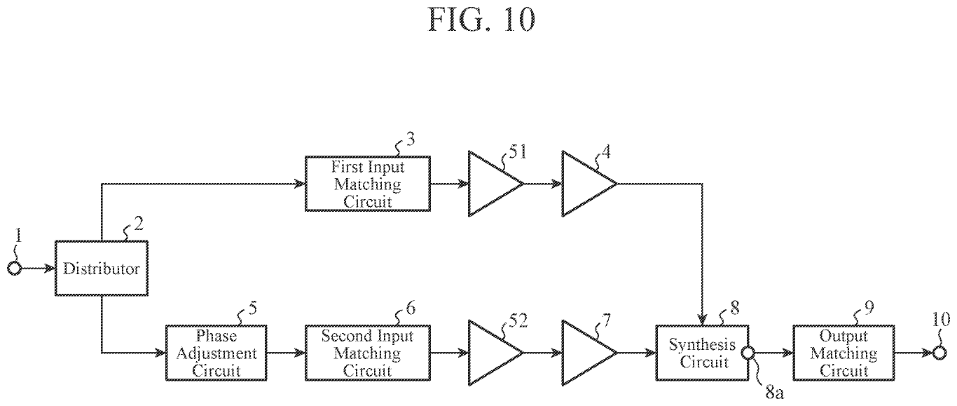

FIG. 10 is a configuration diagram illustrating the Doherty amplifier according to Embodiment 3.

The same reference numerals as those of FIGS. 1 and 9 denote the same or corresponding components in FIG. 10, and therefore description thereof will be omitted.

The amplification element 51 is connected between a first input matching circuit 3 and a carrier amplifier 4.

The amplification element 51 is a similar amplifier to the carrier amplifier 4.

The amplification element 51 amplifies a first signal having passed through the first input matching circuit 3, and outputs the amplified first signal to the carrier amplifier 4.

The Doherty amplifier illustrated in FIG. 10 includes the amplification element 51 provided at a previous stage of the carrier amplifier 4. However, this is merely an example, and the amplification element 51 may be provided at a subsequent stage of the carrier amplifier 4.

The amplification element 52 is connected between a second input matching circuit 6 and a peak amplifier 7.

The amplification element 52 is a similar amplifier to the peak amplifier 7.

The amplification element 52 amplifies a second signal having passed through the second input matching circuit 6, and outputs the amplified second signal to the peak amplifier 7.

The Doherty amplifier illustrated in FIG. 10 includes the amplification element 52 provided at a previous stage of the peak amplifier 7. However, this is merely an example, and the amplification element 52 may be provided at a subsequent stage of the peak amplifier 7.

The amplification elements 51 and 52 are added to the Doherty amplifier illustrated in FIG. 10, so that it is possible to obtain higher gain than that of the Doherty amplifier illustrated in FIG. 1.

The Doherty amplifier illustrated in FIG. 10 is the Doherty amplifier in which the amplification elements 51 and 52 are used and that is illustrated in FIG. 1. However, this is merely an example, and the amplification elements 51 and 52 may be used in the Doherty amplifier illustrated in FIG. 9.

Note that the present disclosure enables flexible combinations of the embodiments or deformation of any components of each embodiment, or omission of any components of each embodiment.

### INDUSTRIAL APPLICABILITY

The present disclosure is suitable for a Doherty amplifier.

### REFERENCE SIGNS LIST

1: input terminal, 2: distributor, 3: first input matching circuit, 4: carrier amplifier, 5: phase adjustment circuit, 6: second input matching circuit, 7: peak amplifier, 8: synthesis circuit, 8a: synthesis point, 9: output matching circuit, 10: output terminal, 11, 12, 13: inductor, 14, 15: capacitor, 21, 22, 23: inductor, 31, 32: capacitor, and 51, 52: amplification element.

1. A Doherty amplifier comprising:
a carrier amplifier to amplify a first signal;
a peak amplifier to amplify a second signal; and
a synthesis circuit to synthesize the first signal amplified by the carrier amplifier and the second signal amplified by the peak amplifier,
wherein the synthesis circuit includes a bandpass filter circuit that includes, as a capacitor, a parasitic capacitance at an output side of each of the carrier amplifier and the peak amplifier.

2. The Doherty amplifier according to claim 1, further comprising a phase adjustment circuit to delay a phase of the second signal and output the second signal after phase adjustment to the peak amplifier,
wherein the phase adjustment circuit includes a bandpass filter circuit, and has a same pass phase characteristic as a pass phase characteristic of the synthesis circuit in an operating frequency band of the Doherty amplifier.

3. The Doherty amplifier according to claim 1, further comprising an output matching circuit to match an impedance of a signal after the synthesis by the synthesis circuit with an impedance of a load.

4. The Doherty amplifier according to claim 1, further comprising:
a distributor to distribute electric power of an amplification target signal to two signals, output one of the two signals after the power distribution as the first signal, and output the other one of the two signals after the power distribution as the second signal;
a first input matching circuit to match an impedance of an input end of the carrier amplifier with an impedance at an input side of the distributor, the first input matching circuit being connected between the distributor and the carrier amplifier; and
a second input matching circuit to match an impedance of an input end of the peak amplifier with the impedance at the input side of the distributor, the second input matching circuit being connected between the distributor and the peak amplifier.
